(19) United States
(12) Patent Application Publication
(10) Pub. No.: US 2012/0105134 A1
(43) Pub. Date: May 3, 2012

(54) Method and Device for Sharing Pin and Functional Device Using the Same

(76) Inventor: Ming-Hung Chang, Hsinchu County (TW)

(21) Appl. No.: 13/008,018

(22) Filed: Jan. 18, 2011

(30) Foreign Application Priority Data
Oct. 29, 2010 (TW) 099137292

(51) Int. Cl. H03H 11/00

(52) U.S. Cl. 327/524

(57) ABSTRACT

A pin sharing method for controlling a plurality of functions of a chip via a versatile pin of the chip is disclosed. The pin sharing method includes dividing a voltage range of the versatile pin into a plurality of sections according to the plurality of functions, and assigning the plurality of sections to correspond to a plurality of modes of the plurality of functions.

### BACKGROUND OF THE INVENTION

1. Field of the Invention

The present invention is related to a pin sharing method and device and related functional device, and more particularly, to a pin sharing method and device and related functional device in which multiple functions share a pin through dividing a voltage range of the pin.

2. Description of the Prior Art

With advances in integrated circuit (IC) manufacturing technology, an IC chip includes more functions. For a digital IC chip, the more functions included, the greater the number of pins required. In general, a pin is utilized for receiving a 1-bit digital signal. That is, the chip merely determines whether a logic “1” or a logic “0” is received by the pin.

However, when the chip is integrated with peripheral circuits to function as an application system, and particularly for a cheap application, hardware implementation space of the chip is limited due to cost concerns, and therefore the chip cannot be packaged with a high number of pins corresponding to chip functions.

Thus, implementing more chip functions with a limited number of pins has been a main focus of the industry.

### SUMMARY OF THE INVENTION

It is therefore a primary objective of the claimed invention to provide a pin sharing method, a pin sharing device and a functional device.

The present invention discloses a pin sharing method for controlling a plurality of functions of a chip via a versatile pin of the chip. The pin sharing method comprises dividing a voltage range of the versatile pin into a plurality of sections according to the plurality of functions, and assigning the plurality of sections to correspond to a plurality of modes of the plurality of functions.

The present invention further discloses a pin sharing device for controlling a plurality of functions of a chip via a versatile pin of the chip. The pin sharing device comprises an input switch for generating a control voltage according to a system control signal, and a division module comprising an input end coupled to the input switch, an output end coupled to the versatile pin, a first power end and a second power end for dividing the control voltage, an upper-limit voltage received by the first power end and a lower-limit voltage received by the second power end to generate an input voltage sent to the versatile pin, wherein a voltage range of the versatile pin is divided into a plurality of sections corresponding to a plurality of modes of the plurality of functions.

The present invention further discloses a functional device for implementing a plurality of functions. The functional device comprises a pin sharing device comprising an input switch for generating a control voltage according to a system control signal, and a division module comprising an input end coupled to the input switch, an output end, a first power end and a second power end for dividing the control voltage, an upper-limit voltage received by the first power end and a lower-limit voltage received by the second power end to generate an input voltage, a versatile pin coupled to the output end for receiving the input voltage, and a chip coupled to the versatile pin for implementing the plurality of the functions according to the input voltage, wherein a voltage range of the versatile pin is divided into a plurality of sections corresponding to a plurality of modes of the plurality of functions.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram of a pin sharing process according to an embodiment of the present invention.

FIG. 2 is a schematic diagram of a functional device according to an embodiment of the present invention.

FIG. 3 is a schematic diagram of a voltage range of a versatile pin of the functional device shown in FIG. 2.

FIG. 4 is a schematic diagram of an input switch and a division module of the functional device shown in FIG. 2.

### DETAILED DESCRIPTION

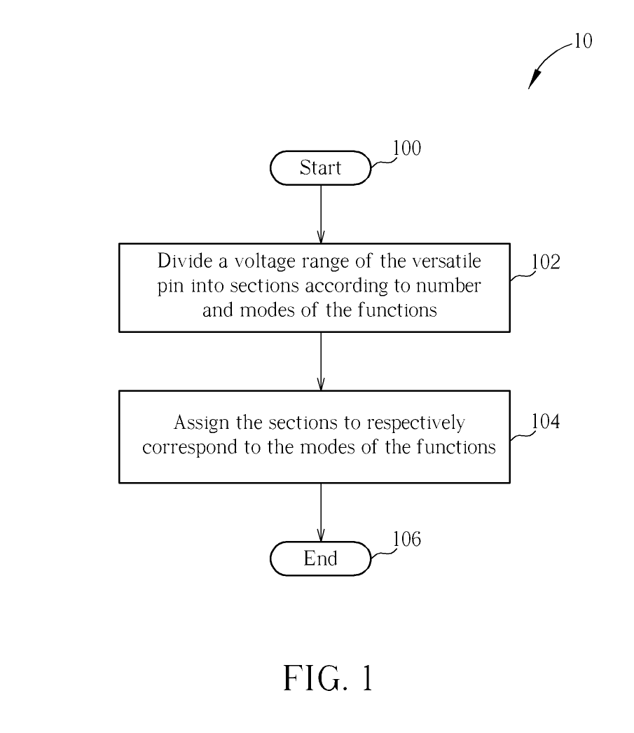

Please refer to FIG. 1, which is a schematic diagram of a pin sharing process 10 according to an embodiment of the present invention. The pin sharing process 10 is utilized for controlling functions of a chip via a versatile pin of the chip, and includes the following steps:

Step 100: Start.

Step 102: Divide a voltage range of the versatile pin into sections according to number and modes of the functions.

Step 102: Assign the sections to respectively correspond to the modes of the functions.

Step 104: End.

In short, to implement the functions with limited pins, the versatile pin is utilized for simultaneously controlling plural functions. To do so, the voltage range of the versatile pin is divided into the sections, and the chip interprets an input signal received by the versatile pin in multiple ways based on default section definitions. That is, a voltage of the versatile pin carries operation mode information of plural functions.

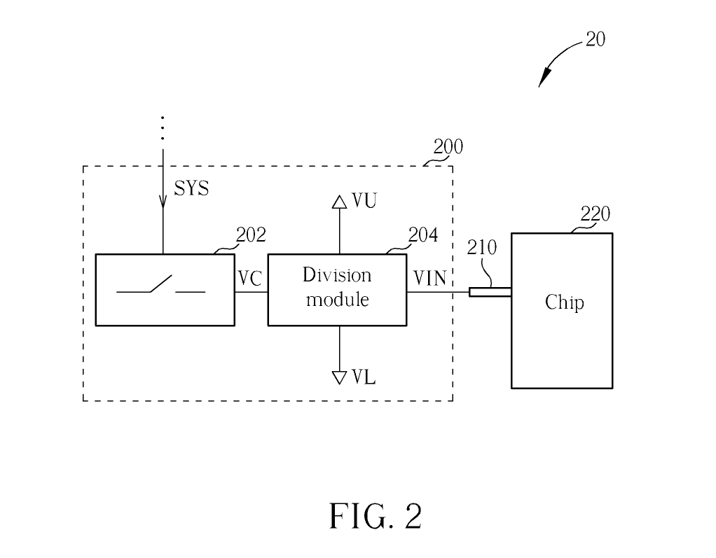

For example, please refer to FIG. 2, which is a schematic diagram of a functional device 20 implementing the pin sharing process 10. The functional device 20 includes a pin sharing device 200, a versatile pin 210 and a chip 220. The pin sharing device 200 includes an input switch 202 and a division module 204. The input switch 202 is utilized for generating a control voltage VC according to a system control signal SYS. The division module 204 is utilized for dividing the control voltage VC, an upper-limit voltage VU and a lower-limit voltage VL to accordingly generate an input voltage VIN. The versatile pin 210 transmits the input voltage VIN to the chip 220. Finally, the chip 220 determines modes of the functions according to the input voltage VIN and correspondence between the sections and the modes, and accordingly performs the functions.

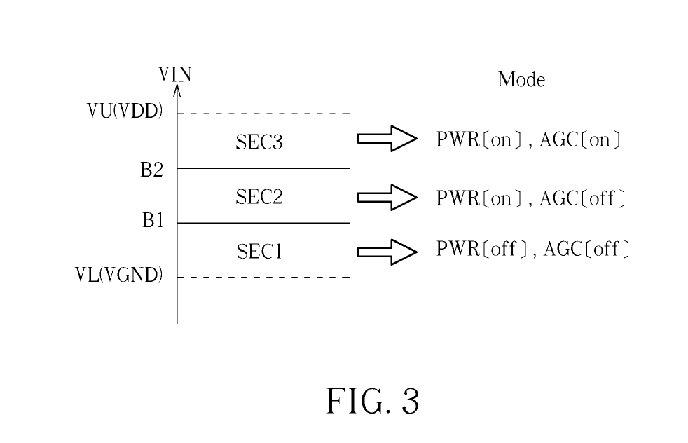

More specifically, assume the chip 220 is an amplifier chip, and the versatile pin 210 is utilized for controlling a power switch function and an auto-gain control (AGC) function. Please refer to FIG. 3, which is a schematic diagram of a voltage range of the versatile pin 210. The voltage range is between the upper-limit voltage VU and the lower-limit voltage VL. In general, to maximize the voltage range, the upper-limit voltage VU is a supply voltage VDD of a digital driver, and the lower-limit voltage VL is a ground voltage VGND. In FIG. 3, the voltage range is divided into sections SEC1, SEC2, SEC3 separated by default boundaries B1, B2. The section SEC1 is between the ground voltage VGND and the default boundary B1, and corresponds to a PWR [off] mode of the power switch function and an AGC [off] mode of the AGC function. The section SEC2 is between the default boundaries B1, B2, and corresponds to a PWR[on] mode of the power switch function and the AGC[off] mode. The section SEC3 is between the supply voltage VDD and the default boundary B2, and corresponds to the PWR[on] mode and an AGC[on] mode of the AGC function. That is, when the input voltage VIN is located in the section SEC1, the chip 220 is powered off, and disables all functions. When the input voltage VIN is located in the section SEC2, the chip 220 is powered on, and amplifies the input voltage VIN. When the input voltage VIN is located in the section SEC3, the chip 220 is powered on, amplifies the input voltage VIN, and activates the AGC function according to a reference voltage Vref to limit the amplified input voltage to avoid damaging a downstream circuit. For example, when the input voltage VIN is located in the section SEC3, a circuit designer can configure the reference voltage Vref=VIN−B2 to broaden the limit for the amplified input voltage with the increasing input voltage VIN. When the input voltage VIN is located in the section SEC2, the reference voltage Vref=VIN−B2<0, and therefore the chip 220 disables the AGC function (AGC[off]).

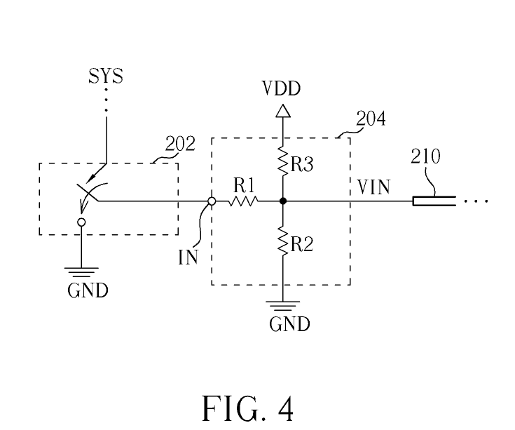

In detail, please refer to FIG. 4, which is a schematic diagram of the input switch 202 and the division module 204 when the chip 220 is an amplifier chip and the versatile pin 210 is utilized for controlling the power switch function and the AGC function. The input switch 202 connects an input end IN of the division module 204 and a ground end GND, or floats the input end IN according to the system control signal SYS. In addition, the division module 204 includes resistors R1, R2, R3 for generating a divided voltage (the input voltage VIN) of the control voltage VC, the supply voltage VDD and the ground voltage VGND. Preferably, the circuit designer can configure R2,R3>>R1. As a result, when the chip 220 needs to operate in the section SEC1, the input switch 202 directly connects the input end IN and the ground end GND to give:

$$VIN = \frac{R 1 // R 2}{R 1 // R 2 + R 3} ( VDD - VGND ) ≅ \frac{R 1}{R 1 + R 3} VDD ≅ 0 ∈ SEC 1$$

When the chip 220 needs to operate in the section SEC2 or the section SEC3, the input switch 292 floats the input end IN to give:

$$VIN = \frac{R 2}{R 2 + R 3} ( VDD - VGND ) ≅ \frac{R 2}{R 2 + R 3} VDD$$

If the AGC function is not required, the circuit designer can configure R2=R3 such that the input voltage VIN=(1/2)VDD. In such a configuration, the chip 220 operates in the section SEC2. If the AGC function is required at startup, the circuit designer can configure R2>R3 to give

$$VIN = \frac{R 2}{R 2 + R 3} VDD ,$$

which is greater than the default boundary B2, such that the chip 220 operates in the section SEC3.

FIG. 3 and FIG. 4 merely illustrate a simple embodiment of circuit design and operation according to the present invention. The novelty of dividing the voltage range can further be applied to a pin controlling more than two chip functions or the like.

In the prior art, the chip merely determines whether a logic “1” or a logic “0” is received by the pin, and accordingly controls a corresponding function. However, a cheap application allows only a limited number of pins, which cannot simultaneously control all chip functions. In comparison, through dividing the voltage range of the versatile pin into sections according to the present invention, different sections may correspond to different modes of multiple functions. Thus, an external control circuit can control multiple chip functions via the versatile pin to reduce the number of employed pins.

Through dividing the voltage range of the versatile pin into sections, the versatile pin controls multiple chip functions, so as to reduce the number of employed pins.

Those skilled in the art will readily observe that numerous modifications and alterations of the device and method may be made while retaining the teachings of the invention.

What is claimed is:

1. A pin sharing method for controlling a plurality of functions of a chip via a versatile pin of the chip, the pin sharing method comprising:
dividing a voltage range of the versatile pin into a plurality of sections according to the plurality of functions; and
assigning the plurality of sections to correspond to a plurality of modes of the plurality of functions.

2. The pin sharing method of claim 1, wherein the plurality of sections are separated by a plurality of default boundaries.

3. The pin sharing method of claim 1, wherein the chip is an amplifier chip, and the plurality of functions comprise a power switch function and an auto-gain control (AGC) function.

4. A pin sharing device for controlling a plurality of functions of a chip via a versatile pin of the chip, the pin sharing device comprising:
an input switch, for generating a control voltage according to a system control signal; and
a division module, comprising an input end coupled to the input switch, an output end coupled to the versatile pin, a first power end and a second power end, for dividing the control voltage, an upper-limit voltage received by the first power end and a lower-limit voltage received by the second power end to generate an input voltage sent to the versatile pin;
wherein a voltage range of the versatile pin is divided into a plurality of sections corresponding to a plurality of modes of the plurality of functions.

5. The pin sharing device of claim 4, wherein the input switch connects the input end with one of at least one voltage source or floats the input end according to the system control signal.

6. The pin sharing device of claim 4, wherein the plurality of sections are separated by a plurality of default boundaries.

7. The pin sharing device of claim 4, wherein the chip is an amplifier chip, and the plurality of functions comprise a power switch function and an auto-gain control (AGC) function.

8. The pin sharing device of claim 4, wherein the voltage range is between the upper-limit voltage and the lower-limit voltage.

9. A functional device for implementing a plurality of functions, the functional device comprising:
a pin sharing device, comprising:
an input switch, for generating a control voltage according to a system control signal; and
a division module, comprising an input end coupled to the input switch, an output end, a first power end and a second power end, for dividing the control voltage, an upper-limit voltage received by the first power end and a lower-limit voltage received by the second power end to generate an input voltage;
a versatile pin, coupled to the output end, for receiving the input voltage; and
a chip, coupled to the versatile pin, for implementing the plurality of the functions according to the input voltage;
wherein a voltage range of the versatile pin is divided into a plurality of sections corresponding to a plurality of modes of the plurality of functions.

10. The functional device of claim 9, wherein the input switch connects the input end with one of at least one voltage source or floats the input end according to the system control signal.

11. The functional device of claim 9, wherein the plurality of sections are separated by a plurality of default boundaries.

12. The functional device of claim 9, wherein the chip is an amplifier chip, and the plurality of functions comprise a power switch function and an auto-gain control (AGC) function.

13. The functional device of claim 9, wherein the voltage range is between the upper-limit voltage and the lower-limit voltage.
